(19) United States
(12) Patent Application Publication
(10) Pub. No.: US 2004/0180536 A1
(43) Pub. Date: Sep. 16, 2004

(54) Method for manufature of semiconductor intergrated circuit device

(76) Inventors: Tsuyoshi Fujiwara, Hamura (JP); Hiroyuki Maruyama, Ome (JP); Naohumi Ohashi, Tokyo (JP); Ken Tsugane, Ome (JP)

Correspondence Address: Stanley P Fisher, Reed Smith, Suite 1400, 3110 Fairview Park Drive, Falls Chruch, VA, 22042-4503, US

(21) Appl. No.: 10/480,457

(22) PCT Filed: Jun. 6, 2002
(86) PCT No.: PCT/JP02/05614

(30) Foreign Application Priority Data
Jun. 12, 2001 (JP) 2001-176977

(51) Int. Cl. H01L 21/4763

(52) U.S. Cl. 438/633; 438/631; 438/629; 438/627; 438/624

(57) ABSTRACT

At the end of a film-forming process of an insulator made of a silicon nitride film by a plasma CVD, introduction of the silane system gas is stopped, and thereafter a plasma discharge is performed for a predetermined time while introduction of the nitrogen-containing gas is continued, and then the plasma discharge is stopped. In this manner, it is possible to nitride an unreacted product on the silicon nitride film and to prevent drawbacks due to the unreacted product.

### TECHNICAL FIELD OF THE INVENTION

The present invention relates to a technique for manufacturing a semiconductor integrated circuit device and, particularly, a technique effectively applied to a technique for forming a silicon nitride film.

### BACKGROUND OF THE INVENTION

In the film-forming technique examined by the inventors of this invention, a silicon nitride film is formed, by the plasma chemical vapor deposition (CVD) using a mixed gas containing a material gas such as silane (SiH₄) and a nitrogen-containing gas. In this case, in a sequence after forming the film, introduction of a material gas such as silane and a plasma discharge are completed almost simultaneously.

However, the inventors have first found out that the technique, in which the introduction of a material gas such as silane and the plasma discharge are completed almost simultaneously after the formation of the silicon nitride film is finished, has the following problem.

That is, there is the problem that unreacted products caused by silane and active species are left on a surface of the formed silicon nitride film and thereby various defects occur.

For example, the inventors have first found out that the following problem occurs in a so-called damascene structure in which a wiring structure is formed by, for example, burying copper (Cu) in grooves for wiring. In the wiring structure, a silicon nitride film is first deposited and then a silicon oxide film is deposited thereon by the CVD method or the like. During the deposition of the silicon oxide film, extremely minute protrusions are formed on the upper surface of the silicon oxide film since the unreacted products left on the silicon nitride film are cores of abnormal growth. Subsequently, the wiring grooves are formed in the silicon oxide film and then a conductive barrier film and a conductor film made of copper are deposited in this order from below on the silicon oxide film and inside the wiring grooves. Next, the conductor film and the conductive barrier film are polished by the chemical mechanical polishing (CMP) method. At this time, if the polishing is performed under the condition of a high selective ratio for the conductive barrier film in order to reduce or prevent dishing and erosion of the conductor film made of copper, unpolished portions of copper and the conductive barrier film are formed around the protrusions due to the protrusions on the upper surface of the underlying silicon oxide film and, as a result, there arises the problem that defects in the short-circuit between adjacent wirings occur.

Note that the technique for damascene wiring is described in Japanese Patent Laid-Open No. 11-135466, which discloses the technique that a polishing agent containing no abrasive particles is used when a conductor film mainly made of copper is polished. Additionally, Japanese Patent Laid-Open No. 2000-150435 discloses the technique that when a lower metal layer corresponding to a conductive barrier film is polished, a polishing rate of an underlying insulator is set lower than that of the lower metal layer. Furthermore, Japanese Patent Laid-Open No. 11-16912 discloses that, after a buried wiring mainly made of copper is formed, an insulator is formed thereon and then openings through which some parts of the buried wiring are exposed are formed in the insulator and, thereafter, a plasma treatment is performed in a reduction atmosphere so as to reduce the parts exposed through the openings.

Also, the inventors have first found out that there arises the following problem in, for example, a manufacturing process of a DRAM (Dynamic Random Access Memory). That is, the manufacturing process of the DRAM includes the steps of: depositing a silicon nitride film; depositing a silicon oxide film thereon; and forming grooves for forming data storage capacitors in the silicon oxide film by using the silicon nitride film as a stopper. In this case, if water washing for removal of foreign matters is performed after the deposition of the silicon nitride film and before the deposition of the silicon oxide film, there arises the problem that the short-circuit failure occurs between the data storage capacitors adjacent to each other due to the above-mentioned unreacted products or the like. This is probably because the above-mentioned unreacted products are reduced by water molecules therein and a subsequent thermal treatment and are transformed to conductive materials.

An object of the present invention is to provide a technique capable of improving a chemical stability on the surface of a silicon nitride film.

The above and other objects and novel characteristics of the present invention will be apparent from the description of the specification and the accompanying drawings.

### DISCLOSURE OF THE INVENTION

Outlines of the typical ones of the inventions disclosed in this application will be briefly described as follows.

That is, the present invention comprises the steps of: at the end of a step of depositing a silicon nitride film over a wafer by a plasma CVD method using a mixed gas of a silane system gas and a nitrogen-containing gas, stopping introduction of the silane system gas; and then performing a plasma discharge for a predetermined time while introduction of the nitrogen-containing gas is continued.

Also, the present invention comprises the steps of: depositing an insulator by a CVD method over a silicon nitride film; forming wiring openings in the insulator; depositing a conductive barrier film over the insulator and inside the wiring openings, and then depositing a conductor film mainly made of copper thereon; and polishing the conductor film and the conductive barrier film so that the films are left in the wiring openings, thereby forming, in the wiring openings, wirings composed of the conductor film and the conductive barrier film.

Additionally, the present invention further comprises the steps of: cleaning an upper surface of a silicon nitride film by the use of a cleaning solution containing water; and depositing an insulator over the silicon nitride film by a CVD method.

### BRIEF DESCRIPTION OF THE DRAWINGS

FIG. 1 is a partially sectional view showing a semiconductor integrated circuit device in the manufacturing process examined by the inventors.

FIG. 2 is a partially sectional view showing the semiconductor integrated circuit device in the manufacturing process subsequent to FIG. 1.

FIG. 3 is a partially sectional view of the semiconductor integrated circuit device in the manufacturing process subsequent to FIG. 2.

FIG. 4 is a partially sectional view of the semiconductor integrated circuit device in the manufacturing process subsequent to FIG. 3.

FIG. 5 is an explanatory diagram of a sequence after a finish of a film-forming process in the manufacturing process of the semiconductor integrated circuit device according to an embodiment of the present invention.

FIG. 6 is a plan view showing a principal part of the semiconductor integrated circuit device in the manufacturing process according to an embodiment of the present invention.

FIG. 7 is a sectional view taken along line X1-X1 in FIG. 6.

FIG. 8 is a sectional view showing a principal part of the semiconductor integrated circuit device in the manufacturing process subsequent to FIGS. 6 and 7.

FIG. 9 is a sectional view showing a principal part of the semiconductor integrated circuit device in the manufacturing process subsequent to FIG. 8.

FIG. 10 is a plan view showing the principal part of the semiconductor integrated circuit device in the manufacturing process subsequent to FIG. 9.

FIG. 11 is a sectional view taken along line X2-X2 in FIG. 10.

FIG. 12 is a sectional view showing a principal part of the semiconductor integrated circuit device in the manufacturing process subsequent to FIGS. 10 and 11.

FIG. 13 is a sectional view showing a principal part of the semiconductor integrated circuit device in the manufacturing process subsequent to FIG. 12.

FIG. 14 is a sectional view showing a principal part of the semiconductor integrated circuit device in the manufacturing process subsequent to FIG. 13.

FIG. 15 is a sectional view showing a principal part of the semiconductor integrated circuit device in the manufacturing process subsequent to FIG. 14.

FIG. 16 is an explanatory diagram showing elemental analyses of a surface portion of a silicon nitride film and upper and lower layers of the silicon nitride film, which are disposed between capacitors in the semiconductor integrated circuit device examined by the present inventors.

FIG. 17 is a sectional view showing a principal part of a semiconductor integrated circuit device in the manufacturing process according to another embodiment of the present invention.

FIG. 18 is a sectional view showing a principal part of the semiconductor integrated circuit device in the manufacturing process subsequent to FIG. 17.

### BEST MODE FOR CARRYING OUT THE INVENTION

Before detailed description of the present invention, the terms used in embodiments of the present invention will be described as follows.

1. A “plasma treatment” means one in which a substitute surface is exposed or, when a member such as an insulator and a metal film is formed on a substrate, a member surface is exposed in a certain plasma environment to give chemical and mechanical (bombardment) functions of the plasma to the surfaces. The plasma is usually formed by, while supplementing a specific gas (treatment gas) into a reaction chamber substituted with the gas as occasion demands, ionizing the gas by action of high-frequency electric field or the like. In practice, however, it is impossible to completely substitute the chamber with the treatment gas. In the present application, therefore, for example, the term “ammonia plasma” does not indicate only the complete ammonia plasma, and permits existence of impurity gases (nitrogen, oxygen, carbon dioxide, water vapor and/or the like) contained in the plasma. Similarly, needless to say, the plasma may contain a dilution gas or additive gas.

2. For example, the term “made of copper” as used herein means that copper is used as a main component. More specifically, the impurity is inevitably contained even in generally high-purity copper, and, thus, the existence of the additives and the impurities in the member made of copper is permitted. This condition is not limited to copper and is similarly applicable to other metal (titanium nitride and the like).

3. The “CMP (Chemical Mechanical Polishing)” means a process in which a surface to be polished is brought into contact with a polishing pad made of a relatively soft sheet material such as a cloth and, in this condition, the polishing pad and the surface are relatively moved in the direction parallel to the surface while slurry is supplied. In this application, other polishing methods, such as the CML (Chemical Mechanical Lapping) in which the surface to be polished is relatively moved to a hard abrasive surface to perform the polishing, methods using other fixed abrasive particles, and the abrasive-free CMP using no abrasive particles, are also available.

4. Abrasive-free chemical mechanical polishing is a method of polishing mainly a conductor film by functions of chemical elements. In this case, a polishing abrasive contains components for forming a protection film and an oxide film on the conductor film made of copper and components for etching an oxide film of copper. The protection film is mainly removed by the contact with polishing pad. In the case where only a small amount of abrasive particles is added, since the abrasive particles have only an auxiliary function of the polishing pad, the polishing rate thereof is scarcely changed. When it comes to the amount of the abrasive particles, the abrasive-free CMP indicates the CMP using slurry in which the abrasive-particle concentration by weight is 0.1 wt % or less, and abrasive CMP indicates the CMP using slurry having concentration higher than the slurry in which the abrasive particle concentration by weight is 0.1 wt % or less. However, these concentrations are relative. In the case where the polishing in a first step is the abrasive-free CMP and the polishing in a second step subsequent thereto is the abrasive CMP, if the abrasive concentration of the first step is lower than that of the second step by a single digit or more, desirably, double digits or more, the polishing in the first step may be represented as the abrasive-free CMP. The abrasive-free CMP in this specification indicates the case where the abrasive-free CMP is used in the entire process for unit planarization of a target metal film and also the case where the abrasive-free CMP is used in a main process and the abrasive CMP is used in a secondary process.

5. “Polishing agent (slurry)” usually indicates suspension in which abrasive particles are mixed in a chemical etching agent. In this application, it also includes a chemical etching agent in which no abrasive particles are mixed.

6. “Abrasive particles (slurry particles)” usually indicate powders of alumina and silica contained in the slurry.

7. “Anticorrosive” indicates a medical agent for forming a protection film with a corrosion resistance and/or hydrophobicity on a metal surface to prevent or suppress process of the polishing by the CMP, and benzotriazole (BTA) or the like is used as the anticorrosive in general (see Japanese Patent Laid-Open No. 8-64594 for details).

8. A “conductive barrier film” indicates a diffraction-barrier conductive film formed relatively thinly on a side surface or a bottom surface of a buried wiring in order to prevent the diffraction of copper into an interlayer insulator or a lower layer. Usually, a refractory metal such as titanium (Ti), tantalum (Ta) and the like, or the nitride thereof (e.g., titanium nitride (TiN) and tantalum nitride (TaN)) are used as the conductive barrier film.

9. A “buried wiring” or “metal-buried wiring” usually indicates a wiring patterned by using a wiring-forming technique in which, similarly to a single or dual damascene, a conductor film is buried in wiring openings such as grooves and holes formed in an insulator and thereafter the unnecessary conductor film on the insulator is removed. Also, the “single damascene” usually indicates a wiring-buried process in which a plug metal and a wiring metal are separately buried in two steps. Similarly, the “dual damascene” usually indicates a wiring-buried process in which a plug metal and a wiring metal are buried in a single step. In general, a copper-buried wiring with a multilayered structure is used in many cases.

10. A “semiconductor integrated circuit device” in this application is not limited to one formed on a single crystal silicon substrate and includes one formed on other substrates such as an SOI (Silicon on Insulator) substrate or a substrate for manufacturing a TFT (Thin Film Transistor) liquid crystal display unless otherwise stated.

11. A “Wafer (circuit board or substrate)” indicates any of: a semiconductor single crystal substrate made of silicon or the like (generally having a round shape; semiconductor wafer), a sapphire substrate, a glass substrate, other insulating or semi-insulating substrate, or a semiconductor substrate used in manufacturing a semiconductor integrated circuit device; and a composite substrate of them.

12. A “semiconductor integrated circuit chip” or “semiconductor chip” (referred to as “chip” hereinafter) indicates one obtained by dividing, into an unit circuit group, wafers whose a wafer step (wafer process or pre-treatment step) is finished.

13. “Silicon nitride” or “silicon nitride film” is not limited to Si₃N₄ and includes an insulator made of nitride of silicon, that is, having a similar composition such as SiₓN_{y} or SiₓN_{y}H_{z}.

The following embodiment will be divided for description into a plurality of sections or embodiments when required as a matter of convenience. However, these sections or embodiments are not irrelevant to each other unless otherwise stated, and the one relates to a modification example, details, a supplementary explanation thereof, or the like of the entire or a part of the others.

Also, in the embodiments described below, when referring to the number of elements (including number of pieces, values, amount, range, and the like), the number of the elements is not limited to a specific number unless otherwise stated or except the case where the number is apparently limited to the specific number in principle. The number larger or smaller than the specified number is also applicable.

Further, in the embodiments described below, it goes without saying that components (including element steps and the like) are not always indispensable unless otherwise stated or except the case where the components are apparently indispensable in principle.

Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. This condition is also applicable to the numerical value and the range described above.

Also, components having the same function are denoted by the same reference symbols throughout the drawings for describing the embodiments, and the repetitive description thereof will be omitted.

Also, through the drawings used in the embodiments, hatching is used in some cases even in a plan view so as to make the drawings easy to see.

Furthermore, in the embodiments of the present invention, a “MISFET” (Metal Insulator Semiconductor Field Effect Transistor) representing a field effect transistor is abbreviated as “MIS”, and a “p channel MISFET” is abbreviated as “pMIS”, and an “n channel MISFET” is abbreviated as “nMIS”.

Hereinafter, the embodiments of the present invention will be described in detail with reference to the drawings.

(First Embodiment)

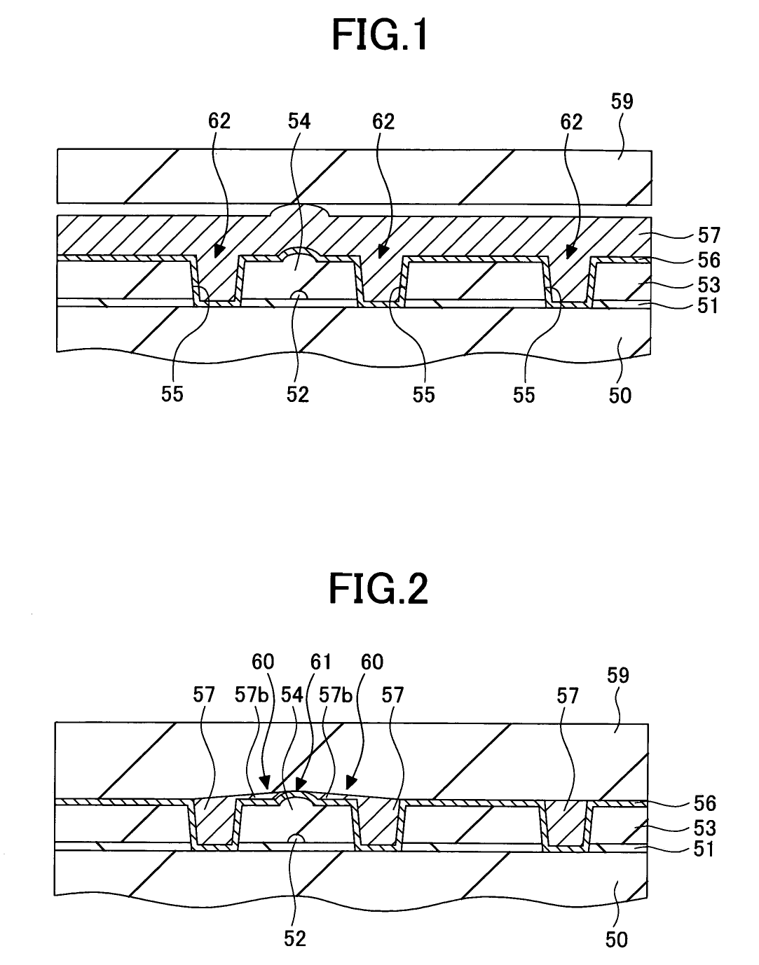

Before the description of a first embodiment, the problems in the techniques examined by the inventors, which are first found by the inventors, will be described with reference to FIGS. 1 to 4.

FIG. 1 is a sectional view showing a principal part of a semiconductor integrated circuit device in the manufacturing process examined by the inventors. On an insulator 50 made of a silicon oxide film or the like, an insulator 51 made of a silicon nitride film or the like is deposited by the CVD (Chemical Vapor Deposition) method. In a process for forming the insulator 51, a mixed gas of a silane (SiH₄) gas, a nitrogen (N₂) gas, and an ammonia (NH₃) gas is used. In the technique examined by the inventors, at the end of the process for forming the insulator 51, the introduction of the silane gas and a plasma discharge are stopped almost simultaneously. In such a sequence, however, an intermediate product 52, such as an unreacted product of un-decomposed silane, and active species, etc. are left in a chamber of a CVD equipment and on a surface of the insulator 51. Since the intermediate product 52 can be represented by the chemical formula SiₓN_{y} (x>y) and has a high degree of activity and is unstable, if an insulator 53 made of a silicon oxide film is deposited on the insulator 51 by the CVD method or the like with the intermediate product 52 present, a plurality of extremely minute protrusions 54, that is, about 1 μm ones are formed on the surface of the insulator 53 due to the intermediate product 52 serving as a core of abnormal growth (In FIG. 1, only one protrusion 54 is shown.). After forming wiring grooves 55 in the above-mentioned insulator 53, a conductive barrier film 56 and a conductor film 57 made of copper are deposited in this order from below on the insulator 53 and inside the wiring grooves 55. A protrusion 57a is formed on the surface of the conductor film 57 due to the protrusion 54 on the surface of the insulator 53.

In such a condition, the above-mentioned abrasive-free CMP is performed with putting a polishing pad 59 onto the surface of the conductor film 57. In this case, the conductor film 57 made of copper is polished mainly by functions of chemical elements. More specifically, a protection film on the conductor film 57 is removed at the contact surface with the polishing pad 59, and the copper is oxidized and etched. However, in the above-mentioned polishing process, as shown in FIG. 2, peripheral portions 60 around the protrusion 54 cannot follow the polishing pad 59 and, thereby, the protection film cannot be removed. Therefore, unpolished portions 57b of the conductor film 57 made of copper are formed. Meanwhile, at a top portion 61 of the protrusion 54, the conductive barrier film 56 is exposed and progress of the polishing is stopped.

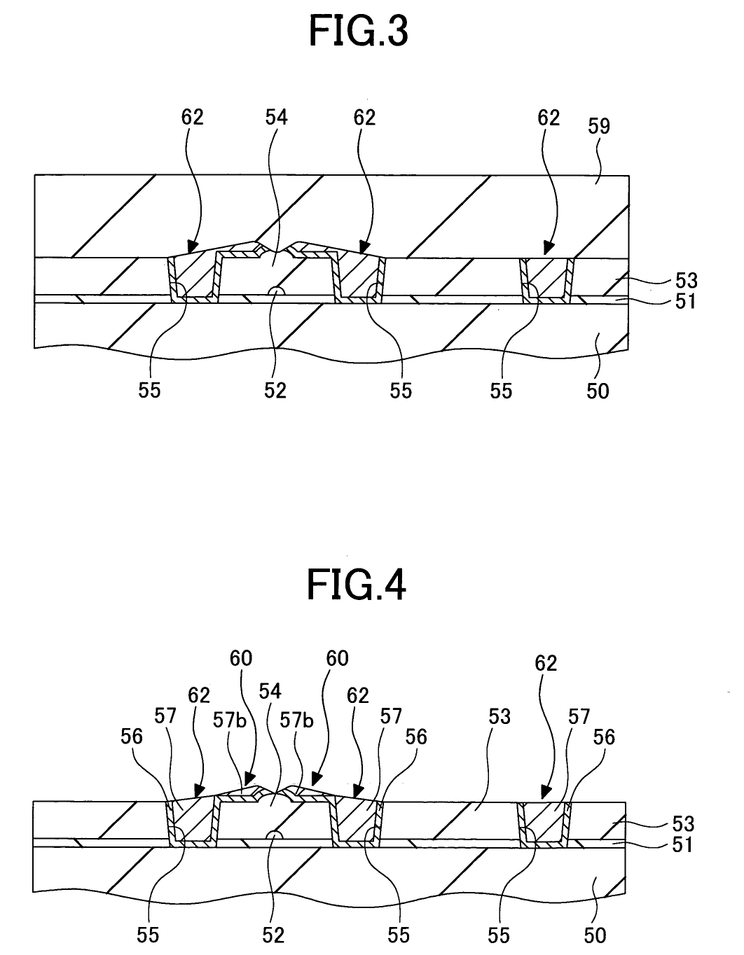

In this state, a process of the abrasive CMP is started. In this case, the conductive barrier film 56 with standard elements is mainly polished, namely, the polishing process is performed under the condition that an etching rate of copper is set lower than that of the conductive barrier film 56 from the viewpoint of the prevention of the dishing and erosion of the copper, etc. Accordingly, as shown in FIG. 3, in an area in which the unpolished portions 57b each made of copper exist (in the peripheral portions 60 around the protrusion 54), the unpolished portions 57b each function as an etching mask and the polishing of the underlying conductive barrier film 56 does not progress. Therefore, as shown in FIG. 4, on and around the protrusion 54, the conductive barrier film 56 below the unpolished portions 57b is left. As a result, adjacent buried wirings 62 and 62 to interpose the protrusion 54 therebetween are short-circuited through the residual part of the conductive barrier film 56. More specifically, although this method can reduce the dishing and erosion of copper and also reduce variation of each thickness of the buried wirings 62, it increases potentials for occurrence of defects in the short circuit between the wirings due to the protrusion 54.

For its solution, in this embodiment, in a process for forming an insulator made of a silicon nitride film by a plasma CVD method, a silane system gas in a treatment gas is first stopped at the end thereof and the flow of a gas containing nitrogen (N) is continued, and the plasma discharge is continuously performed for a predetermined time while the vacuum condition at the film-forming process is maintained. Thereafter, the plasma discharge is stopped to finish the film-forming process. In this manner, it becomes possible to nitride the above-described intermediate product formed in the chamber of the CVD equipment for forming the silicon nitride film and formed on the silicon nitride film, thereby allowing chemical stability on the surface of the formed silicon nitride film to be improved. Particularly, the experiment by the inventors recognizes that an advantageous effect can be obtained when the plasma discharge is continuously performed after stopping flow of a monosilane gas (SiH₄).

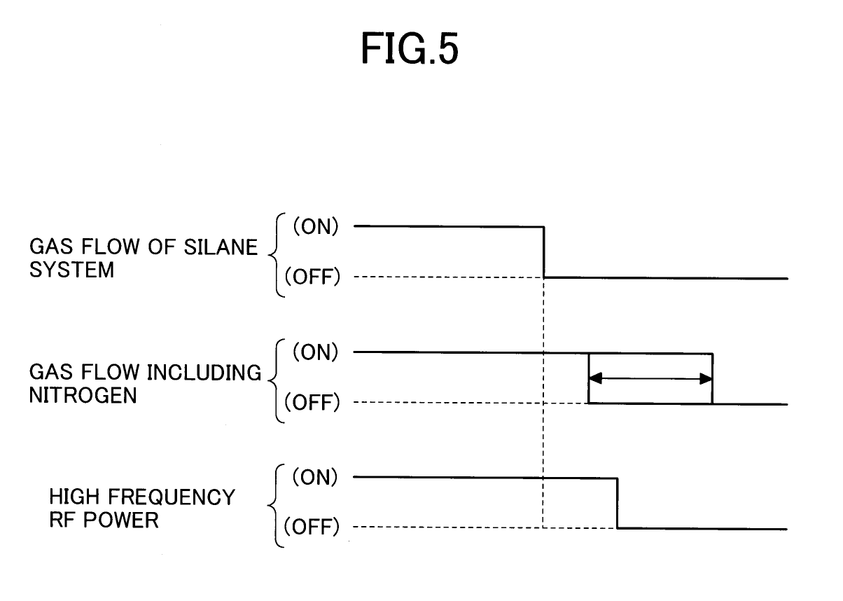

FIG. 5 shows a on/off sequence of a silane system gas, a gas containing nitrogen, and radio frequency power at the end of the film-forming process for the silicon nitride film in the first embodiment. The timing at which the flow of the nitrogen-containing gas is stopped may arbitrarily set if time for the plasma discharge is ensured, and the timing may be set at any time before and after the “OFF” of the radio frequency (RF) power, as illustrated by an range of arrows, if it is after stop of the flow of the silane system gas. The time for the plasma discharge after the stop of the flow of the silane system (e.g., monosilane (SiH₄)) gas cannot generally be determined because it depends on a reaction rate of the CVD equipment. However, for example, approximately 1 to 3 seconds are preferable. In the experiment by the inventors, the plasma discharge for approximately 3 seconds is performed, and it is recognized that the plasma discharge for approximately 1 second is also effective. The pressure in the chamber of the CVD equipment in this case is in a range of, for example, 133.322 to 1333.22 Pa (1 to 10 Torr), and was, for example, 666.612 Pa (5 Torr) in the experiment.

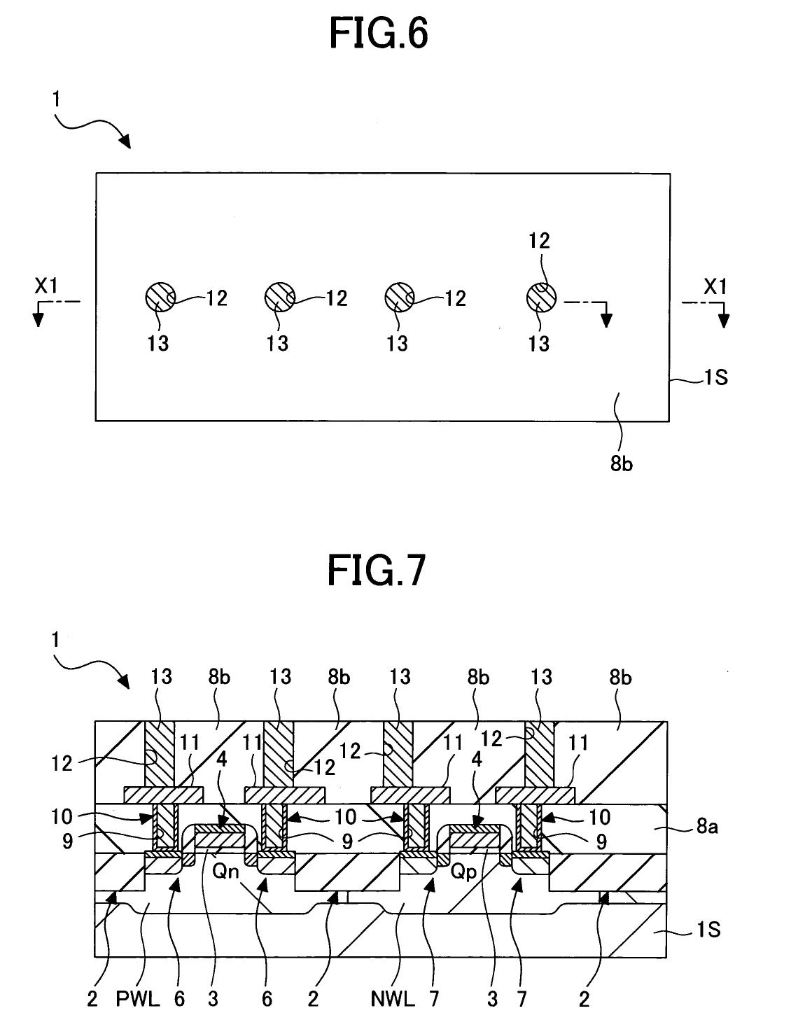

Next, a concrete example of the manufacturing method of a semiconductor integrated circuit device according to this embodiment will be described with reference to FIGS. 6 to 14.

FIG. 6 is a plan view showing a principal part of a wafer 1 in the manufacturing process of the semiconductor integrated circuit device, and FIG. 7 is a sectional view taken along line X1-X1 in FIG. 6. A semiconductor substrate (hereinafter simply referred to as “substrate”) 1S constituting the wafer 1 is made of p type single crystal silicon with a specific resistance of, for example, approximately 1 to 10 Ωcm. Shallow groove isolations (SGI) 2 are formed in a main surface (device-forming surface) of the substrate 1S. The groove isolations 2 are formed by, for example, embedding a silicon oxide film in grooves formed in the main surface of the substrate 1S. Also, p well PWL and n well NWL are formed in the main surface of the substrate 1S. For example, boron is introduced into the p well PWL, and phosphorus is introduced to the n well NWL. A nMIS Qn and a pMIS Qp are formed in respective active regions of the p well PWL and the n well NWL surrounded by the above-mentioned isolations 2.

Gate insulators 3 of the nMIS Qn and the pMIS Qp are made of a silicon oxide film with a thickness of, for example, approximately 6 nm. The thickness of the gate insulator 3 mentioned here means conversion thickness by silicon oxide (hereinafter simply referred to as “conversion thickness”) and, therefore, may not sometimes be equal to the actual thickness. The gate insulator 3 may be constituted from a silicon oxynitride film instead of a silicon oxide film. More specifically, it may have a structure in which nitrogen is segregated at an interface between the gate insulator 3 and the substrate 1S. Since the silicon oxynitride film has an advantageous effect to suppress generation of interfacial levels and to reduce electron trap in the film in comparison to the silicon oxide film, it is possible to improve the hot-carrier resistance of the gate insulator 3 and the dielectric strength. Furthermore, since the silicon oxynitride film has such a property that impurities are hard to penetrate through in comparison to the silicon oxide film, the use of the silicon oxynitride film makes it possible to reduce variation in threshold voltages caused by diffusion of the impurities in the material of the gate electrode to a side of the substrate 1S. The silicon oxynitride film may be formed by, for example, a thermal treatment of the substrate 1S in an atmosphere containing a nitrogen gas such as NO, NO₂ or NH₃. Also, the same effect as the above-mentioned one can be obtained by: forming the gate insulator 3 made of silicon oxide on the respective surfaces of the p well PWL and the n well NWL; thereafter performing the thermal treatment to the substrate 1S in the above-mentioned nitrogen-gas-containing atmosphere; and making segregation of nitrogen at the interface between the gate insulator 3 and the substrate 1S.

Additionally, the gate insulator 3 may be formed by, for example, a silicon nitride film, or a compound insulator of a silicon oxide film and a silicon nitride film. When the thickness of the gate insulator 3 made of a silicon oxide film is reduced to become below 5 nm in the above-mentioned conversion thickness, particularly, below 3 nm, the generation of direct tunnel currents and the reduction in insulation breakdown voltages by the hot carrier due to the stress become actual. Since the silicon nitride film has a dielectric constant higher than that of the silicon oxide film, the conversion thickness thereof is smaller than the actual thickness. More specifically, in the case where the gate insulator is made of a silicon nitride film, even if the silicon nitride film is physically thick, it is possible to obtain capacity equivalent to that of the relatively thin silicon dioxide film. Therefore, when a single silicon nitride film or a compound film of it and a silicon oxide film is used to form the gate insulator 3, effective film thickness of the gate insulator 3 can be made larger than that of the gate insulator constituted by a silicon oxide film. Therefore, it becomes possible to reform the generation of tunnel leakage currents and the reduction in insulation breakdown voltages by the hot carrier.

Gate electrodes 4 of the nMIS Qn and the pMIS Qp are each obtained by forming, for example, a titanium silicide (TiSiₓ) layer or a cobalt silicide (CoSiₓ) layer on a low-resistance polycrystalline silicon film. However, the gate electrode structure is not limited to this, and may be a so-called polymetal gate structure constituted by, for example, a laminated film of a low-resistance polycrystalline silicon film, a WN (tungsten nitride) film, and a W (tungsten) film. Sidewalls 5 each made of, for example, silicon oxide are formed on side surfaces of the gate electrodes 4.

Semiconductor regions 6 for a source and drain of the nMIS Qn include an n⁻ type semiconductor region adjacent to a channel, and an n⁺ type semiconductor region connected to the n⁻ type semiconductor region and provided at a position away from the channel up to the length of the n⁻ type semiconductor region. For example, phosphorus or arsenic is introduced into the n⁻ type semiconductor region and the n⁺ type semiconductor region. Meanwhile, semiconductor regions 7 for a source and drain of the pMIS Qp include a p⁻ type semiconductor region adjacent to a channel, and a p⁺ type semiconductor region connected to the p⁻ type semiconductor region and provided at a position away from the channel up to the length of the p⁻ type semiconductor region. For example, boron is introduced into the p⁻ type semiconductor region and the p⁺ type semiconductor region. On a part of each upper surface of the semiconductor regions 6 and 7, a silicide layer such as a titanium silicide layer or a cobalt silicide layer is formed.

An insulator 8a is deposited over the above-described substrate 1S. The insulator 8a is made of a film with good reflow characteristics capable of embedding the narrow spaces of the gate electrodes 4 and 4, for example, a BPSG (Boron-doped Phospho Silicate Glass) film. Additionally, it may be constituted by an SOG (Spin on Glass) film formed by a spin coating method. Contact holes 9 are formed in the insulator 8a. Some parts on the respective upper surfaces of the semiconductor regions 6 and 7 are exposed through bottoms of the contact holes 9. Plugs 10 are formed in the contact holes 9. The plugs 10 are, for example, formed by: depositing a titanium nitride (TiN) film and a tungsten (W) film on the insulator 8a and inside the contact holes 9 by the CVD method or the like; thereafter removing the unnecessary titanium nitride film and tungsten film on the insulator 8a by the CMP or etch back method; and leaving these films only in the contact holes 9.

First layer wirings 11 each made of, for example, tungsten are formed on the insulator 8a. The first layer wirings 11 are electrically connected respectively to the semiconductor regions 6 and 7 for the sources and drains of the nMIS Qn and pMIS Qp and to the gate electrode 4 through the plugs 10. Also, an insulator 8b made of, for example, a silicon oxide film is deposited on the insulator 8a so as to cover the first layer wirings 11. Through holes 12, through which parts of the first layer wirings 11 are exposed, are formed in the insulator 8b. Plugs 13 made of, for example, tungsten are formed in the through holes 12.

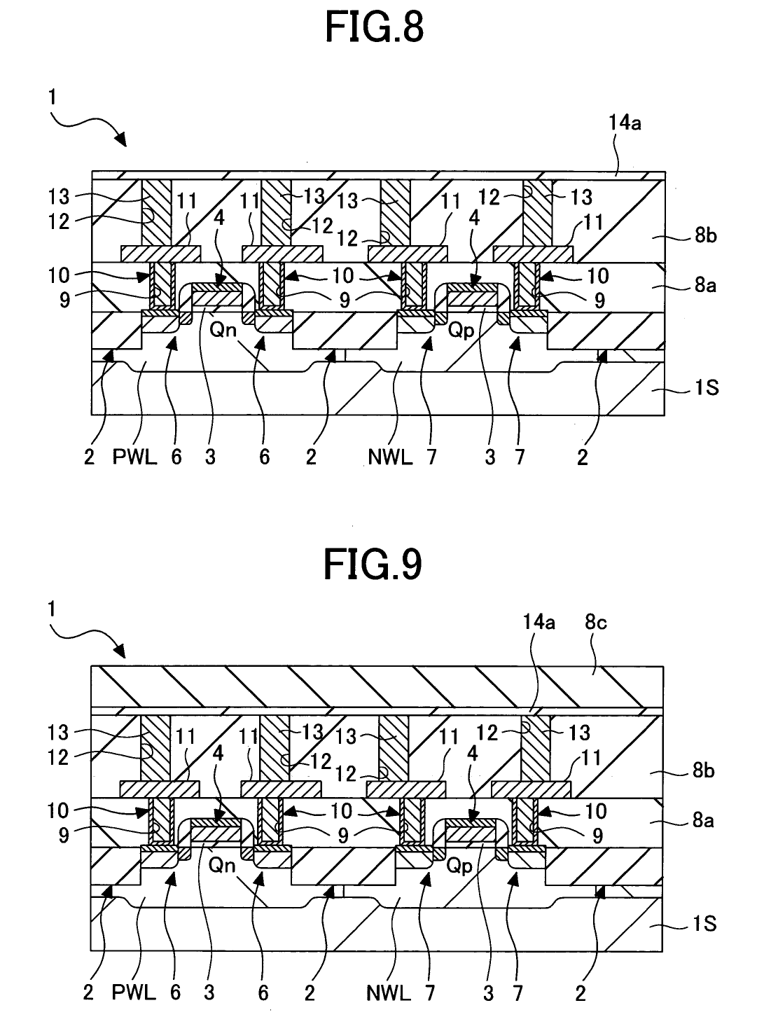

FIG. 8 is a sectional view showing a principal part of the semiconductor integrated circuit device in the manufacturing process subsequent to FIGS. 6 and 7. First, in this embodiment, as shown in FIG. 8, an insulator 14a made of, for example, a silicon nitride film or the like with a thickness of 50 nm is deposited on the main surface of the above-described wafer 1 by the plasma CVD method or the like. The deposition conditions thereof are as follows. That is, a mixed gas of, for example, a monosilane gas (SiH₄), a nitrogen (N₂) gas, and an ammonia (NH₃) gas is used as a treatment gas. The deposition time cannot be completely determined because depending on the thickness of the film to be formed. However, it is, for example, 3 to 30 seconds, and approximately 5 to 20 seconds in this case. The pressure in the chamber is, for example, approximately 133.322 to 1333.22 Pa (1 to 10 Torr) and, in practice, for example, approximately 666.612 Pa (5 Torr). In this embodiment, the flow of the monosilane (SiH₄) gas is stopped at the end of the film-forming process for the insulator 14a, and, in this state, the nitridation of the wafer 1 is performed as described above. More specifically, after the introduction of the monosilane (SiH₄) gas is stopped at the end of the film-forming process, the flow of at least one of the nitrogen gas and the ammonia gas into the chamber is continued, and the plasma (nitrogen plasma and ammonia plasma) discharge is continuously performed for a predetermined time while the vacuum condition is maintained. Thereafter, the plasma discharge is stopped. In this manner, it becomes possible to nitride the intermediate product formed in the chamber and on the surface of the insulator 14a, thereby allowing the chemical stability on the surface of the insulator 14a to be improved.

FIG. 9 is a sectional view showing a principal part of the semiconductor integrated circuit device in the manufacturing process subsequent to FIG. 8. As shown in FIG. 9, an insulator 8c made of, for example, a silicon oxide film is deposited on the insulator 14a by the plasma CVD method or the like using a mixed gas of a TEOS (Tetraethoxysilane) gas and an ozone (O₃) gas. In this embodiment, when the insulator 8c is deposited, the intermediate product to be the core does not exist on the surface of the insulator 14a made of a silicon nitride film and the insulator 14a has high surface stability. Therefore, it becomes possible to deposit the insulator 8c without getting a plurality of minute protrusions formed on the surface of the insulator 8c.

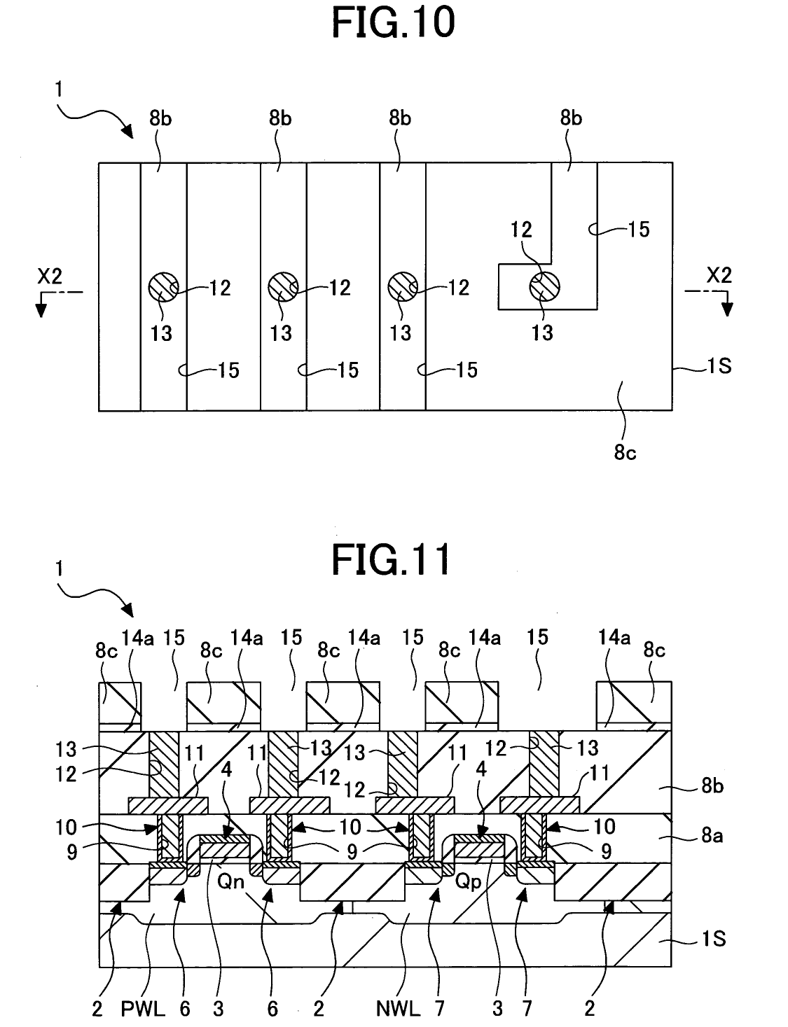

FIG. 10 is a plan view showing a principal part of the semiconductor integrated circuit device in the manufacturing process subsequent to FIG. 9, and FIG. 11 is a sectional view taken along line X2-X2 in FIG. 10. In this case, the insulators 8c and 14a are selectively removed by the dry etching using a photoresist film as an etching mask to form wiring grooves (openings for wiring) 15. To form the wiring grooves 15, the insulator 14a is made to function as an etching stopper, by making high respective etching selective ratios of the insulator 8a and the insulator 14a in removing the insulator 8c exposed through the photoresist film. More specifically, the etching treatment is performed under the condition that the etching rate of the insulator 8c is higher than that of the insulator 14a. Then, after temporarily stopping the etching of the surface of the insulator 14a, the insulator 14a exposed through the wiring grooves 15 in this step is selectively removed. This can improve the accuracy of the depths of the wiring grooves 15, and also prevent the overetching in forming the wiring grooves 15. The planar shape of each wiring groove 15 is, for example, a strip shape as shown in FIG. 10. The upper surfaces of the plugs 13 are exposed at the bottom surfaces of the wiring grooves 15, respectively.

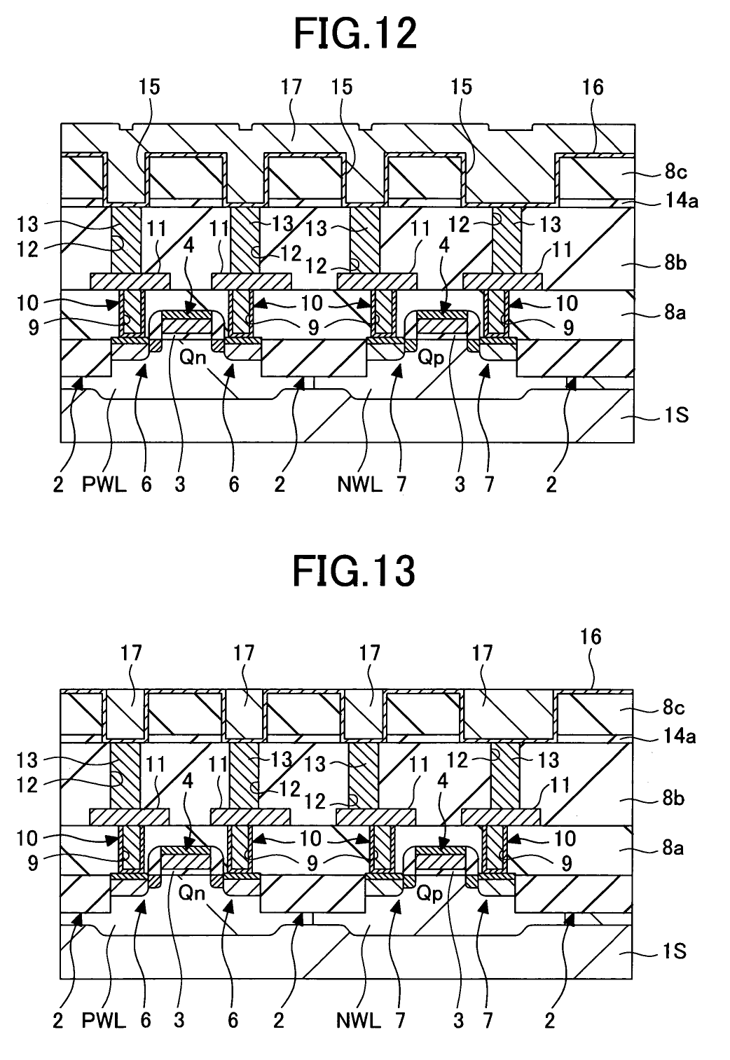

Next, FIG. 12 is a sectional view showing a principal part of the semiconductor integrated circuit device in the manufacturing process subsequent to FIGS. 10 and 11. In this case, buried wirings are formed in the wiring grooves 15 in the manner as follows. That is, as shown in FIG. 12, a conductive barrier film 16 made of titanium nitride (TiN) or the like with a thickness of, for example, approximately 40 to 50 nm is first deposited on the entire main surface of the wafer 1 by the sputtering method or the like. This conductive barrier film 16 has functions to prevent the diffusion of copper for forming a main conductor film described later, to improve the adhesiveness between the main conductor film and the insulators 8b, 8c, and 14a, and to improve the wettability of copper at reflow of the main conductor film. As a film with the functions mentioned above, refractory metal nitride almost unreacted with copper, such as tungsten nitride (WN) and tantalum nitride (TaN), is preferably used instead of titanium nitride. Additionally, materials obtained by adding silicon (Si) to the refractory metal nitride, and refractory metals hardly reacted with copper, such as tantalum (Ta), titanium (Ti), tungsten (W), and a titanium-tungsten (TiW) alloy, can be preferably used instead of titanium nitride. In this embodiment, since there are no minute protrusions on the surface of the underlying insulator 8c, it is possible to form the conductive barrier film 16 having uniform thickness without any unevenness on its surface.

Subsequently, a main conductor film 17 made of copper with a relatively large thickness of approximately 800 to 1600 nm is deposited on the conductive barrier film 16. In this embodiment, since there are no minute protrusions on the surface of the underlying conductive barrier film 16, it is possible to form the main conductor film 17 having the uniform thickness without any unevenness on its surface. The plating method is used in forming the main conductor film 17. By using the plating method, the main conductor film 17 can be effectively buried and formed at low cost. In this case, a thin conductor film made of copper is deposited on the conductive barrier film 16 by the sputtering method, and then a relatively thick conductor film made of copper is grown thereon by, for example, the electroplating method or the electroless plating method, and the main conductor film 17 is deposited. In this plating process, a plating solution based on, for example, copper sulfate is used.

However, it is also possible to form the main conductor film 17 by the sputtering method. As the method for forming the conductive barrier film 16 and the main conductor film 17, a standard sputtering method may be used, and in order to improve burying properties and film quality, a high directional sputtering method such as a long-throw sputtering method and a collimate sputtering method is preferable used. Additionally, the main conductor film 17 can be also formed by the CVD method.

Subsequently, a thermal treatment is performed to the wafer 1 in a non-oxidizing atmosphere (e.g., hydrogen atmosphere) at, for example, approximately 475° C. to reflow the main conductor film 17, whereby copper is buried into the wiring grooves 15 so as to leave no spaces therebetween. In this embodiment, the minute protrusions are hardly present on the surface of the underlying insulator 8c even by using any of the above-mentioned film-forming methods, whereby the minute protrusions corresponding to them can hardly be present also on the surfaces of the conductive barrier film 16 and the main conductor film 17.

Next, in this embodiment, the main conductor film 17 and the conductive barrier film 16 are polished by the CMP (Chemical Mechanical Polishing) process in first and second steps as follows.

First, the purpose of the first step is to selectively polish the main conductor film 17 made of copper, by the above-mentioned abrasive-free CMP process. The polishing agent contains an anticorrosive agent for forming a protection film, an oxidizer of copper, and a component for etching an oxide film of copper, but no abrasive particles. For example, BTA is used as the anticorrosive agent. For example, hydrogen peroxide (H₂O₂) is used as the oxidizing agent. It is also possible to contain the abrasive particles up to approximately 3 to 4% of the total of the polishing agent. In this case, the main conductor film 17 is mainly polished by the chemical element while both of the protective effect and the etching effect for the main conductor film 17 are exerted. The protection film is mainly removed by the contact with the polishing pad. The hard polishing pad is employed from the viewpoint of enhancement of the flatness. However, a soft one may be employed (the second step subsequent thereto is also the same). The polishing rate of the main conductor film 17 made of copper is, for example, approximately 500 nm/min, and that of the conductive barrier film 16 is, for example, approximately 3 nm/min. The polishing time is not particularly limited because it depends on the thickness of the main conductor film 17. However, it is, for example, approximately 2 to 4 minutes in the case of the above-mentioned thickness.

FIG. 13 is a sectional view showing a principal part of the semiconductor integrated circuit device in the manufacturing process subsequent to FIG. 12 after the first step. By such polishing process, the main conductor film 17 in regions other than the wiring grooves 15 is polished as shown in FIG. 13. In this embodiment, no protrusions due to the intermediate product are present on the surface of the insulator 8c by the first step and thereby no protrusions are formed also on the surface of the conductive barrier film 16. Therefore, it is possible to appropriately polish the main conductor film 17, without forming any unpolished portions of the main conductor film 17 made of copper on the conductive barrier film 16 in regions other than the wiring grooves 15. Particularly, since it is possible to make uniform the thickness of the main conductor film 17 made of copper, a degree of freedom in the control of the selection ratio with the conductive barrier film 16 can be improved. Additionally, since there is no unevenness on the surface of the underlying conductive barrier film 16, it is possible to reduce the overpolished amount of the film. Therefore, the removal amount of the main conductor film 17 to be left in the grooves 15 can be reduced. Accordingly, the increase and variation in the wiring resistance due to the overpolishing can be suppressed or prevented.

The purpose of the subsequent second step is to selectively polish the conductor barrier film 16 by the above-mentioned abrasive CMP process. In this second step, the conductive barrier film 16 is mainly polished by a mechanical element such as the contact with the polishing pad. In this case, in addition to the anticorrosive agent for forming a protection film, an oxidizer of copper, and a component for etching a oxide film of copper, the abrasive particles are contained therein. As the abrasive particles, for example, silica (SiO₂) or alumina (Al₂O₃) is used. The additive amount of the abrasive particles is set to such a amount that the underlying insulator 8c is not removed, and it may be, for example, 1 wt % or less and is set to, for example, approximately 0.8 wt % in this case. Additionally, the amount of oxidizing agent in the second step is smaller than that in the first step. More specifically, the amount of the anticorrosive agent in the polishing agent is relatively increased. By so doing, the second step can strengthen the protection of the main conductor film 17 made of copper while suppressing the oxidation thereof. Therefore, it becomes possible to prevent excessive removal of the main conductor film 17, and also suppress or prevent the dishing and/or erosion. This can suppress or prevent the increase and variation in the wiring resistance, whereby the performance of the semiconductor integrated circuit device can be improved. The polishing rate of the conductive barrier film 16 is, for example, approximately 80 nm/min, and that of the main conductor film 17 made of copper is, for example, approximately 7 nm/min, and that of the underlying insulator 8c is, for example, approximately 3 nm/min. The polishing time cannot be particularly limited because it depends on the thickness of the conductive barrier film 16. However, it is, for example, approximately 1 minute in the case of the above-mentioned thickness.

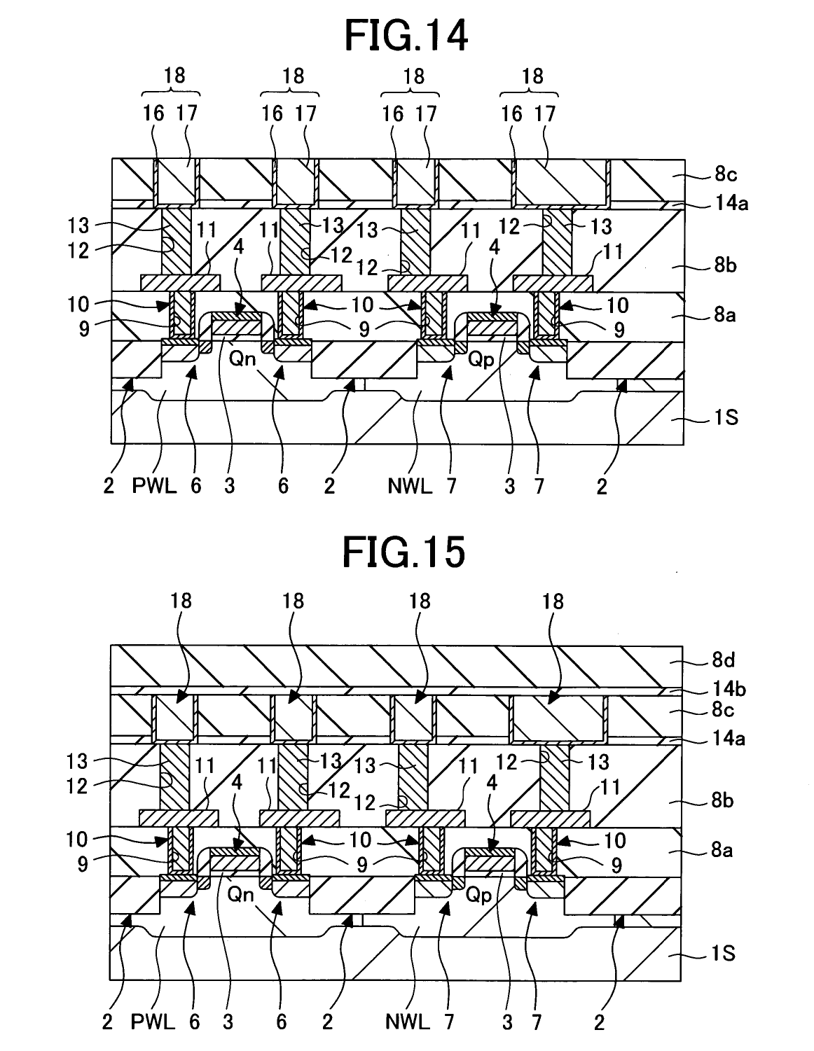

FIG. 14 is a sectional view showing a principal part of the semiconductor integrated circuit device in the manufacturing process subsequent to FIG. 13 after the second step. By the above-mentioned polishing process, buried second layer wirings 18 are formed in the wiring grooves 15. The buried second layer wiring 18 is composed of a relatively thick conductive barrier film 16 and the relatively thick main conductor film 17, and is electrically connected to the first layer wiring 11 through the plug 13. In this embodiment, since no unpolished portions of the main conductor film 17 made of copper are present, during the polishing process in the second step, on the conductive barrier film 16 in regions other than the wiring grooves 15, it is possible to appropriately polish the conductive barrier film 16 without generating any unpolished portion. Therefore, the defects of the short-circuit between the adjacent buried wirings due to the unpolished portions of the conductive barrier film 16 or the like can be prevented, whereby the reliability and the yield of the semiconductor integrated circuit device can be improved. Additionally, since it is possible to make uniform the thickness of the conductive barrier film 16, a degree of freedom in the control of the selection ratio with the main conductor film 17 made of copper can be improved. Also, since there is no unevenness on the surface of the conductive barrier film 16, it is possible to reduce the overpolished amount of film. Therefore, the removal amount of the main conductor film 17 to be left in the grooves 15 can be reduced, and the increase and variation in the wiring resistance due to the overpolishing can be suppressed or prevented.

Next, FIG. 15 is a sectional view showing a principal part of the semiconductor integrated circuit device in the manufacturing process subsequent to FIG. 14. In this case, an insulator 14b made of, for example, the same material as that of the insulator 14a is formed on the main surface of the wafer 1 using the same film-forming method and the same sequence at the end of the film formation as those of the insulator 14a. Thereafter, an insulator 8d made of, for example, the same material as that of the insulator 8c is formed on the insulator 14b by using the same film-forming method as that of the above-mentioned insulator 8c.

(Second Embodiment)

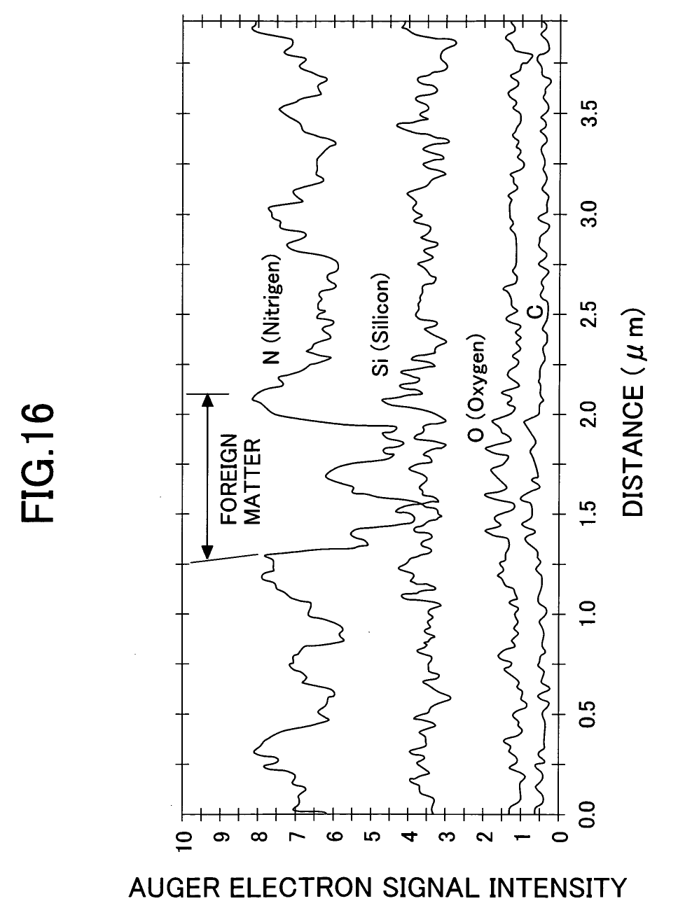

Before description of a second embodiment, the problems in the technique examined by the inventors, which are first found by the inventors, will be described with reference to FIG. 16.

The manufacturing process of the semiconductor integrated circuit device examined by the inventors is, for example, a manufacturing process of a DRAM (Dynamic Random Access Memory). The manufacturing method of the DRAM includes the steps of: depositing a silicon nitride film on a substrate by the CVD method; then depositing a silicon oxide film thereon; and forming, further in the silicon nitride film, openings for capacitors of data storage capacitors while the above-mentioned silicon nitride film is made to function as an etching stopper. The inventors have first found out the problem that when the silicon nitride film is deposited and then a cleaning process is performed by purified water in order to remove foreign matters on the surface thereof, the defects of the short-circuit occurs between the adjacent capacitors. Therefor, the surface of the silicon nitride film is examined, and conductive foreign matters are observed between the adjacent capacitors. FIG. 16 shows the results of AES elemental analyses (Auger electron signal intensity in the Auger analysis) in the surface portion of the silicon nitride film between the capacitors and in the upper and lower layers of the silicon nitride film, and the peak of Si element is observed in a range of the presence of the foreign matters. This is probably because the above-mentioned unreacted product or the like left on the surface of the silicon nitride film is reduced by water and a subsequent thermal treatment due to the above-mentioned reason and is changed into a conductive substance.

Therefore, also in this second embodiment, the sequence described with reference to FIG. 5 is applied at the end of the film-formation of the silicon nitride film. By so doing, similarly to the first embodiment, since an intermediate product is not formed on the surface of the silicon nitride film, it is possible to suppress or prevent occurrence of the defects of the short circuit between the capacitors due to the intermediate product.

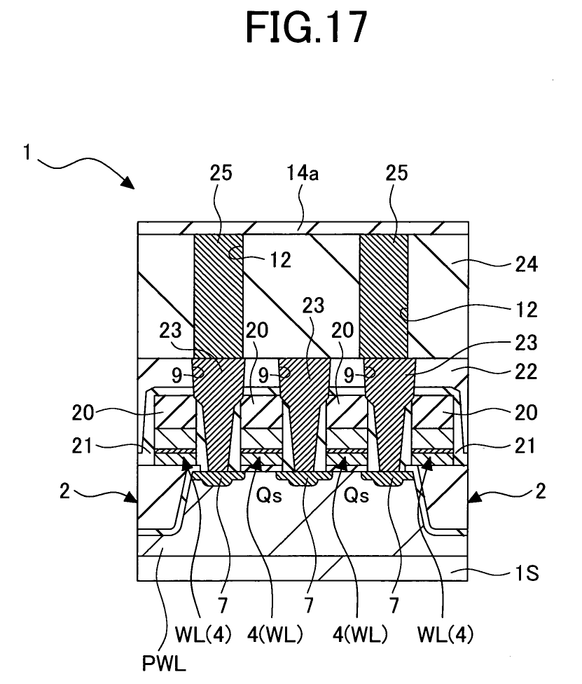

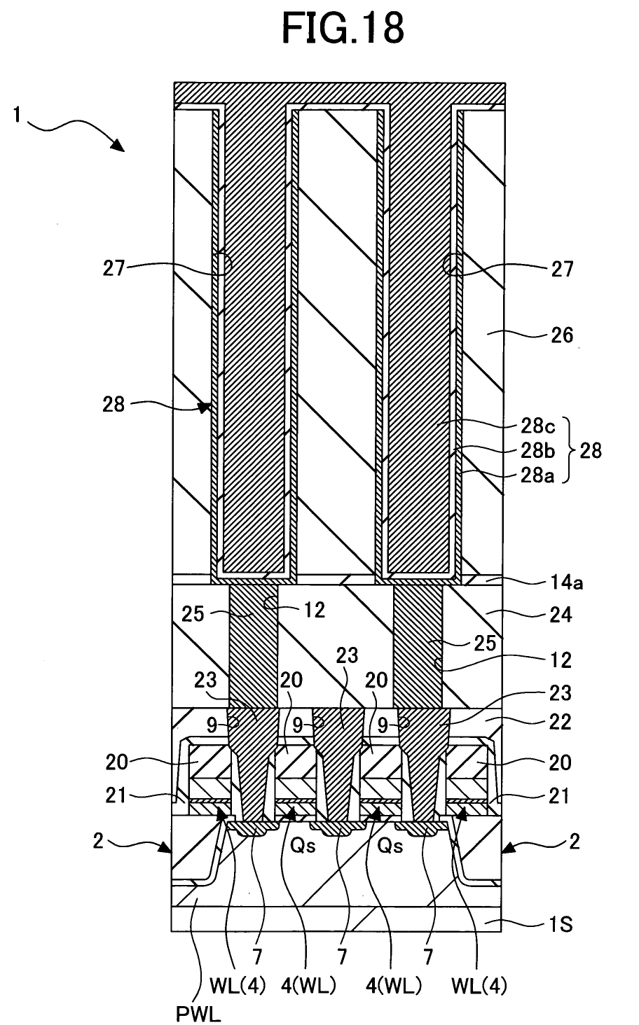

Next, an example of the manufacturing method of the DRAM will be described with reference to FIGS. 17 and 18.

FIG. 17 is a sectional view showing a principal part of the DRAM in the manufacturing process. Similarly to the first embodiment, the substrate 1S of the wafer 1 is made of, for example, p type single crystal silicon. The groove isolations 2 are formed in the isolation regions on the main surface of the substrate 1S, similarly to the first embodiment. The active regions surrounded by the isolations 2 are formed to plane island-shaped patterns, and a plurality of the active regions are regularly arranged in a memory cell region. For example, two memory cell selecting MIS Qs are formed in each of the active regions so as to have in common one of the respective semiconductor regions for source and drain.

The memory cell selecting MIS Qs is, for example, an nMIS, which has the same structure as that of the nMIS Qn described in the first embodiment. More specifically, the MIS Qs has the semiconductor regions 7 for source and drain, the gate insulator 3, and the gate electrode 4. The gate electrode 4 is constituted by a part of a word line WL and has the above-mentioned polymetal gate structure. A cap insulator 20 made of, for example, a silicon nitride film is formed over the gate electrode 4. Except these, the gate insulator 3 and the semiconductor region 7 are identical to those in the first embodiment, and so the description thereof will be omitted here.

Additionally, the insulator 21 is made of, for example, a silicon nitride film, and is deposited over the gate electrode 4, on the surface (upper and side surfaces) of the cap insulator 20 and on the main surface of the substrate 1. Furthermore, an insulator 22 made of, for example, a silicon oxide film is deposited on the insulator 21. The contact holes 9 are formed in the insulators 21 and 22. Plugs 23 are embedded in the contact holes 9. The plug 23 is made of, for example, a low-resistance polycrystalline silicon film and is electrically connected to the semiconductor region 7. An insulator 24 made of, for example, a silicon oxide film is deposited over the insulator 21. Through holes 12 are formed in the insulator 24. Plugs 25 made of, for example, tungsten are embedded in the through holes 12. The plugs 25 are electrically connected to the right and left plugs 23 of the above-mentioned plugs 23. Note that the central plug 23 is electrically connected to a data line. The insulator 14a made of, for example, a silicon nitride film is formed on the insulator 24 by using the same film-forming method and the same sequence at the end of the film formation as those of the first embodiment. Therefore, there is no intermediate product formed on the surface of the insulator 14a. Accordingly, the surface of the insulator 14a is in a chemically stable state.

After forming the insulator 14a as described above, the surface of the insulator 14a is cleaned using purified water or the like. By so doing, the foreign matters adhered to the surface of the insulator 14a can be removed. This allows the yield and the reliability of the DRAM to be improved. Additionally, since the surface of the insulator 14a is in the chemically stable state, occurrence of the conductive foreign matters due to the above-mentioned intermediate product can be suppressed or prevented.

FIG. 18 is a sectional view showing a principal part of the DRAM in the manufacturing process subsequent to FIG. 17. In this case, an insulator 26 made of, for example, a silicon oxide film is deposited on the insulator 14a by the CVD or coating method or the like, and then openings 27 for forming capacitors are formed in the insulator 26. During the step of forming the openings 27, the etching process is performed under the condition that a high etching selective ratio is maintained between the silicon oxide film and the silicon nitride film. More specifically, the etching process is initially performed under the condition that the etching rate of the silicon oxide film is higher than that of the silicon nitride film, and thereby the insulator 14a is made to function as an etching stopper. Thereafter, the etching process is performed again under the condition that the etch rate of the silicon nitride film is higher than that of the silicon oxide film. By so doing, since it becomes possible to prevent the overetching in forming the openings 27 for capacitors, the yield and the reliability of the DRAM can be improved.

Subsequently, for example, crown-shaped capacitors 28 are formed in the openings 27. The capacitor 28 is composed of a lower electrode 28a, a capacitor insulator 28b, and an upper electrode 28c. The lower electrode 28a is made of, for example, a low-resistance polycrystalline silicon film and is electrically connected to the plug 25. The capacitor insulator 28a is made of, for example, a dielectric film such as tantalum pentoxide (Ta₂O₅) and is sandwiched between the lower electrode 28a and the upper electrode 28c. The upper electrode 28c is composed of, for example, a tungsten silicide (WSiₓ) film laminated on a low-resistance polycrystalline silicon film. In the process for forming the capacitors 28, the thermal treatment is added.

In the second embodiment, the intermediate product is not formed on the insulator 14a even if a water cleaning process is performed after the formation of the insulator 14a and the thermal treatment is added in the process for forming the capacitors. Therefore, the occurrence of the conductive foreign matters due to the intermediate product can be prevented. Accordingly, the defects of the short circuit occurring between the capacitors 28 can be suppressed or prevented, whereby the yield and the reliability of the DRAM can be improved.

In the foregoing, the invention made by the inventors thereof has been concretely described based on the embodiments. However, needless to say, the present invention is not limited to the foregoing embodiments, and can be variously changed and modified without departing from the gist thereof.

For example, the case where the monosilane gas, the nitrogen gas, and the ammonia gas are used as the treatment gas in the process for forming the silicon nitride film has been described in the first and second embodiments. However, the treatment gas is not limited to them, and, for example, a mixed gas of a disilane (Si₂H₆) gas (silane system gas), a nitrogen gas, and an ammonia gas may be used as the treatment gas.

Also, in the second embodiment, the case where the data storage capacitor is formed into a crown shape has been described. However, the shape of the capacitor is not limited to this and can be variously modified. For example, it may be formed into a fin shape.

In the foregoing description, the case where the invention by the inventors is applied to the manufacturing method of a semiconductor integrated circuit device having a CMIS circuit and the manufacturing method of a DRAM, which belong to the industrial field in the background of the present invention, has been described. However, the present invention is not limited to this, and can be, for example, applied to: a manufacturing method of a semiconductor integrated circuit devices having a memory circuit such as an SRAM (Static Random Access Memory) and a flash memory (EEPROM: Electric Erasable Programmable Read Only Memory), etc; a manufacturing method of a semiconductor integrated circuit device having a logic circuit such as a microprocessor; or a manufacturing method of a mixed semiconductor integrated circuit device in which a memory circuit and a logic circuit are provided on the same semiconductor substrate. Additionally, the present invention can be also applied to a manufacturing method of a liquid crystal substrate and a micro-machine. At least, the present invention can be applied to the case where a silicon nitride film is formed by the plasma CVD method.

The advantages achieved by the typical ones of the inventions disclosed in this application will be briefly described as follows.

(1) At the end of the step of depositing the silicon nitride film on the wafer by the plasma CVD method using the mixed gas of a silane system gas and a nitrogen-containing gas, the introduction of the silane system gas is stopped and, then, the plasma discharge is performed for a predetermined time while the introduction of the nitrogen-containing gas is continued. In this manner, the unreacted product or/and the like is not formed on the silicon nitride film. Therefore, it is possible to improve the chemical stability on the surface of the silicon nitride film.

(2) As a result of item (1), it becomes possible to suppress or prevent the formation of the minute protrusions, on the surface of the insulator deposited on the silicon nitride film. Therefore, the defects of the short circuit occurring between the adjacent wirings due to the protrusions can be suppressed or prevented.

(3) As a result of item (2), since it becomes possible to clean the silicon nitride film by using the cleaning solution containing water, the foreign matters on the surface of the silicon nitride film can be removed. Therefore, it is possible to improve the reliability and the yield of the semiconductor integrated circuit device.

### INDUSTRIAL APPLICABILITY

The present invention can be, for example, applied to: a manufacturing method of a semiconductor integrated circuit device; a manufacturing method of a liquid crystal substrate; and a manufacturing method of a micro-machine.

1. A method for manufacturing a semiconductor integrated circuit device, the method comprising the steps of:
at the end of a step of depositing a silicon nitride film over a wafer by a plasma chemical vapor deposition method using a mixed gas of a silane system gas and a nitrogen-containing gas, stopping introduction of said silane system gas;
performing a plasma discharge for a predetermined time while introduction of said nitrogen-containing gas is continued; and
thereafter completing the plasma discharge.

2. The method for manufacturing a semiconductor integrated circuit device according to claim 1,
wherein a process of said plasma discharge is continuously transferred from a film-forming process of said silicon nitride film while a vacuum condition is maintained.

3. The method for manufacturing a semiconductor integrated circuit device according to claim 1, further comprising the step of:
after a film-forming process of said silicon nitride film, depositing an insulator over the silicon nitride film by a chemical vapor deposition method.

4. The method for manufacturing a semiconductor integrated circuit device according to claim 3,
wherein said insulator is made of a material capable of having a high etching selective ratio to said silicon nitride film.

5. The method for manufacturing a semiconductor integrated circuit device according to claim 3,
wherein said insulator is made of a material having a dielectric constant relatively lower than that of said silicon nitride film.

6. A method for manufacturing a semiconductor integrated circuit device, the method comprising the steps of:
(a) depositing a silicon nitride film over a wafer by a plasma chemical vapor deposition method using a mixed gas of a silane system gas and a nitrogen-containing gas; and
(b) depositing an insulator over said silicon nitride film,
wherein, at the end of a film-forming step of said silicon nitride film, introduction of said silane system gas is stopped, and a plasma discharge is performed for a predetermined time while introduction of said nitrogen-containing gas is continued, and thereafter the plasma discharge is completed.

7. The method for manufacturing a semiconductor integrated circuit device according to claim 6,
wherein a process of said plasma discharge is continuously transferred from a film-formation process of said silicon nitride film while a vacuum condition is maintained.

8. The method for manufacturing a semiconductor integrated circuit device according to claim 6,
wherein said insulator is formed by a chemical vapor deposition method.

9. The method for manufacturing a semiconductor integrated circuit device according to claim 6,
wherein said insulator is made of a material capable of having a high etching selective ratio to said silicon nitride film.

10. The method for manufacturing a semiconductor integrated circuit device according to claim 6,
wherein said insulator is made of a material having a dielectric constant relatively lower than that of said silicon nitride film.

11. A method for manufacturing a semiconductor integrated circuit device, the method comprising the steps of:
(a) depositing a silicon nitride film over a wafer by a plasma chemical vapor deposition method using a mixed gas of a silane system gas and a nitrogen-containing gas;
(b) depositing an insulator over said silicon nitride film by a chemical vapor deposition method;
(c) forming wiring openings in said insulator;
(d) depositing a conductive barrier film on said insulator and inside said wiring openings, and thereafter depositing a conductor film thereon; and
(e) polishing said conductor film and said conductive barrier film so that the films are left in said wiring openings, thereby forming, in said wiring openings, wirings composed of said conductor film and said conductive barrier film,
wherein, at the end of a film-forming step of said silicon nitride film, introduction of said silane system gas is stopped, and a plasma discharge is performed for a predetermined time while introduction of said nitrogen-containing gas is continued, and thereafter the plasma discharge is completed.

12. The method for manufacturing a semiconductor integrated circuit device according to claim 11,
wherein a process of said plasma discharge is continuously transferred from a film-forming process of said silicon nitride film while a vacuum condition is maintained.

13. The method for manufacturing a semiconductor integrated circuit device according to claim 11,
wherein said insulator is made of a material capable of having a high etching selective ratio to said silicon nitride film.

14. The method for manufacturing a semiconductor integrated circuit device according to claim 11,
wherein said insulator is made of a material having a dielectric constant relatively lower than that of said silicon nitride film.

15. The method for manufacturing a semiconductor integrated circuit device according to claim 11,
wherein said conductor film is made of copper or a copper alloy.

16. The method for manufacturing a semiconductor integrated circuit device according to claim 11,
wherein said step (e) comprises:
a first step of polishing said conductor film by a chemical element; and
a second step of polishing said conductor barrier film by a mechanical element.

17. The method for manufacturing a semiconductor integrated circuit device according to claim 16,
wherein said first step uses a polishing agent containing no polishing abrasives or containing an amount of polishing abrasives smaller than that of a polishing agent used in said second step.

18. The method for manufacturing a semiconductor integrated circuit device according to claim 16,
wherein, in said first step, said conductor film is polished while both of a protective effect and a etching effect on said conductor film are exerted.

19. The method for manufacturing a semiconductor integrated circuit device according to claim 16,
wherein polishing in said first step is performed under the condition that said conductor film is polished more easily than said conductive barrier film.

20. The method for manufacturing a semiconductor integrated circuit device according to claim 16,
wherein polishing in said second step is performed under the condition that said conductive barrier film is polished more easily than said conductor film.

21. The method for manufacturing a semiconductor integrated circuit device according to claim 16,
wherein the polishing in said second step is performed under the condition that said conductive barrier film is more polished than said insulator.

22. A method for manufacturing a semiconductor integrated circuit device, the method comprising the steps of:
(a) depositing a silicon nitride film over a wafer by a plasma chemical vapor deposition method using a mixed gas of a silane system gas and a nitrogen-containing gas;
(b) cleaning said silicon nitride film by the use of a cleaning solution containing water; and
(c) depositing an insulator over said silicon nitride film by a chemical vapor deposition method,
wherein, at the end of a film-forming step of said silicon nitride film, introduction of said silane system gas is stopped, and a plasma discharge is performed for a predetermined time while introduction of said nitrogen-containing gas is continued, and thereafter the plasma discharge is completed.

23. The method for manufacturing a semiconductor integrated circuit device according to claim 22, further comprising the step of:
forming an opening for forming a data storage capacitor devices in said insulator.

24. The method for manufacturing a semiconductor integrated circuit device according to claim 22,
wherein a process of said plasma discharge is continuously transferred from a film-forming process of said silicon nitride film while a vacuum condition is maintained.

25. The method for manufacturing a semiconductor integrated circuit device according to claim 22,
wherein said insulator is made of a material capable of having a high etching selective ratio to said silicon nitride film.

26. The method for manufacturing a semiconductor integrated circuit device according to claim 22,
wherein said insulator is made of a material having a dielectric constant relatively lower than that of said silicon nitride film.

27. A method for manufacturing a semiconductor integrated circuit device, the method comprising the steps of:
at the end of a step of depositing a silicon nitride film over a wafer by a plasma chemical vapor deposition method using a mixed gas containing a predetermined material gas, a plasma discharge is performed for a predetermined time while introduction of said material gas is stopped; and
thereafter completing the plasma discharge.
